(19) United States
(12) Patent Application Publication
(10) Pub. No.: US 2014/0167074 A1
(43) Pub. Date: Jun. 19, 2014

(54) Intensity Scattering LED Apparatus

(71) Applicant: WAITRONY OPTOELECTRONICS LIMITED, Tsuen Wan (CH)

(72) Inventor: Khok Hing-Wai, Hong Kong (CN)

(73) Assignee: Waitrony Optoelectronics Limited, Tsuen Wan (CN)

(21) Appl. No.: 13/716,586

(22) Filed: Dec. 17, 2012

(51) Int. Cl. H01L 33/08; H01L 27/144

(52) U.S. Cl. CPC H01L 33/08; H01L 27/144
USPC 257/81; 257/88

(57) ABSTRACT

An Intensity Scattering LED apparatus which comprises an uneven surface on the tip of the epoxy encapsulation layer of the LED to act as a scattering lens such that the light beam on the normal line, relative to the light source, is scattered and the intensity to the human eye or human body is decreased. Simultaneously, the light beams that are not on the normal line are unchanged, and moreover, the total intensity and the brightness of the LED remain unchanged. In the instant invention, no reductions in driving current or additional diffusing agents are needed to decrease the intensity and the brightness of the LED and may be structured as Pin Packaging having two or more supporting legs and/or SMD (Surface Mount Device) Packaging having no supporting leg but having two or more connecting pads.

### FIELD OF INVENTION

The present disclosure relates generally to light emitting diodes (LED's) and, more particularly, to a LED apparatus with intensity scattering control.

### BACKGROUND

Light-emitting diodes (LED) may have a basic structure comprising a few components such as a light-emitting wafer which can emit visible light (such as Red, Orange, Yellow, Green, Blue, and Violet, i.e., the full spectrum of visible light and its combination and/or emit invisible light such as infrared or ultraviolet), and comprise some sort of structural housing, bonding agent (such as glue), and conductive coupling wires (such as gold, aluminum, copper, silver, or other alloy). Bonding agents may be used as a silver epoxy or silicone epoxy, and one or more light-emitting wafer may be bonded together and coupled via conductive wires. The epoxies may form a head of some sort of resin, and may take on different encapsulation shapes, which generate different illumination appearances and different spotlighting effects.

FIG. 1 illustrates a simple LED structure 50 known in the prior art. The LED structure 50 shows a basic structure of an LED comprising a light-emitting wafer 1, a lead frame 2, bonding agent 3 and a coupling wire 4. The lead frame 2 is coated with the bonding agent 3. One or more wafers 1 are affixed via the bonding agent 3, and the coupling wire 4 is connected to the lead frame 2 to provide an electrical current flow. An epoxy resin 5, or other insulation glue, is used for encapsulating the lead frame 2 within the circuit.

FIG. 2 is a schematic diagram showing the light beams 6 emitting from the LED 50 to the human eye 7 and human body. The major intensity of the light beam that may be harmful to the human eye and/or human body concentrates on the normal line 8, and is depicted by light beam 9.

One of the traditional methods to reduce the intensity to a safety level is to reduce the driving current so as to reduce the intensity of the light beam 9 on the normal line 8. However this method also reduces the total intensity of the LED such that the LED is not bright enough.

Another convention is to add the diffusing agent into the epoxy resin. FIG. 3 illustrates a principle diagram that describes how the light beams 11 emit from the LED 60, the epoxy resin 10 of which is mixed with diffusing agent. The light beams 11 are scattered. Although the intensity of the light beam on the normal line 8 is reduced, the total intensity of the LED is likewise reduced such that the overall LED emission lacks sufficient brightness and intensity.

The above-mentioned conventional method are lacking in that although the safety level can be achieved by reducing intensity, the total intensity of the LED is thus reduced and the LED will then lack sufficient brightness.

Accordingly, there is a need to overcome such lacking methods described above by a simplistic design that can be easily reproduced with readily obtainable materials, thus reducing the major intensity on the normal line but at the same time keeping the total intensity and brightness of the LED unchanged.

### SUMMARY OF THE INVENTION

The present invention addresses the above-described deficiencies and others. Specifically, this invention can overcome the problems in the prior LED devices by increasing safety while not compromising the total intensity and the brightness of the LED.

In the description herein, numerous specific details are provided, such as examples of components and/or methods, to provide a thorough understanding of embodiments of the present invention. One skilled in the relevant art will recognize, however, that an embodiment of the invention can be practiced without one or more of the specific details, or with other apparatus, systems, assemblies, methods, components, materials, parts, and/or the like. In other instances, well-known structures, materials, or operations are not specifically shown or described in detail to avoid obscuring aspects of embodiments of the present invention.

The novel features which are characteristic of the invention, as to organization and method of use, together with further objects and advantages thereof, will be better understood from the following disclosure considered in connection with the accompanying drawings in which one or more preferred embodiments of the invention are illustrated by way of example. It is to be expressly understood, however, that the drawings are for the purpose of illustration and description only and are not intended as a definition of the limits of the invention.

As used herein, the term “comprises” refers to a part or parts of a whole, but does not exclude other parts. That is, the term “comprises” is open language that requires the presence of the recited element or structure or its equivalent, but does not exclude the presence of other elements or structures. The term “comprises” has the same meaning and is interchangeable with the terms “includes” and “has”. The term set has the meaning of one or more of said element. Furthermore, any use of the term “or” as used herein is generally intended to mean “and/or” unless otherwise indicated. Combinations of components or steps will also be considered as being noted, where terminology is foreseen as rendering the ability to separate or combine is unclear.

### BRIEF DESCRIPTION OF THE DRAWINGS

Embodiments of the present disclosure are described herein with reference to the drawings, in which:

FIG. 1 is a diagram of a simple LED structure known in the prior art;

FIG. 2 is a diagram of a principle diagram that describes how the light beams emit from the LED to the human eye and human body known in the prior art;

FIG. 3 is a diagram of a principle diagram that describes how the light beams emit from the LED with epoxy resin mixed with diffusing agent to the human eye and human body known in the prior art;

FIG. 4 is a schematic diagram of an Intensity Scattering LED structure in accordance with certain embodiments of the current invention; and

FIG. 5 is a schematic diagram illustrating the light beam emissions from the Intensity Scattering LED to the human eye and human body in accordance with certain embodiments of the current invention.

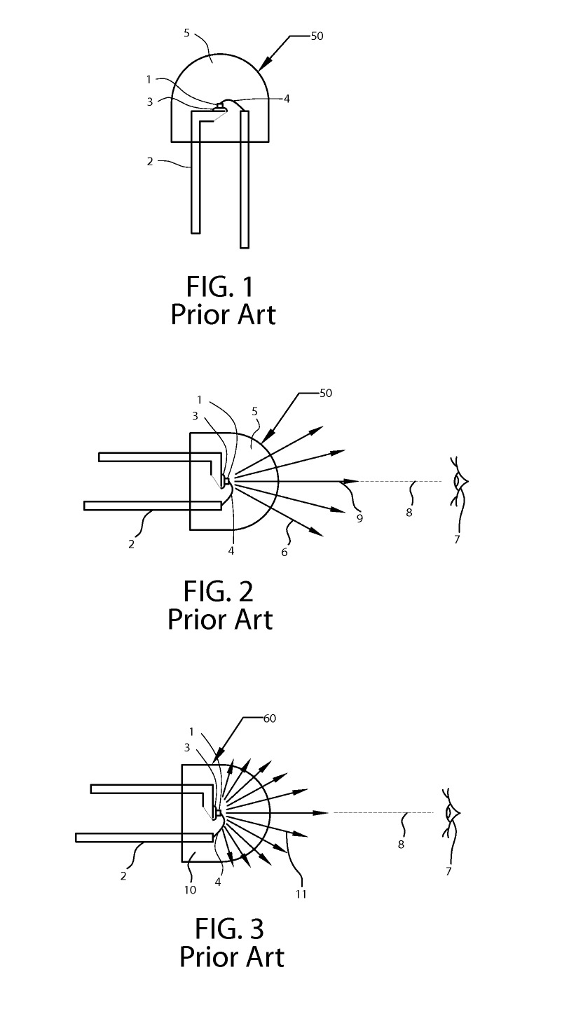

### DETAILED DESCRIPTION

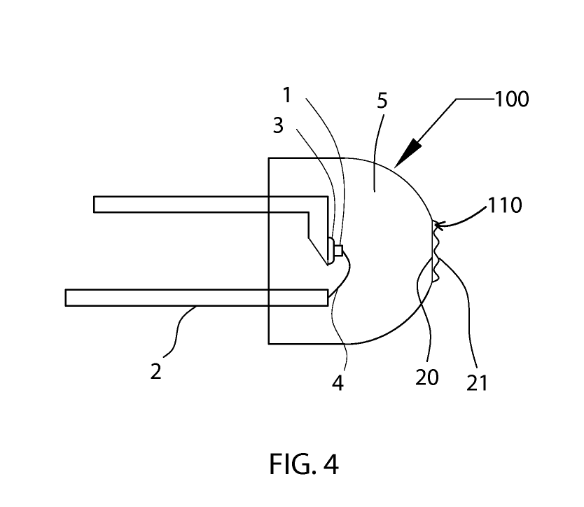

FIG. 4 illustrates a simplified structure of an Intensity Scattering LED 100 that comprises the basic structure of LED and additional new structure. The basic structure of an LED comprises a light-emitting wafer 1, a lead frame 2, bonding agent 3 and a coupling wire 4. The lead frame 2 is coated with the bonding agent 3. One or more wafers 1 are affixed via the bonding agent 3, and the coupling wire 4 is connected to the lead frame 2 to provide an electrical current flow. An epoxy resin 5, or other insulation glue, is used for encapsulating the lead frame 2 within the circuit.

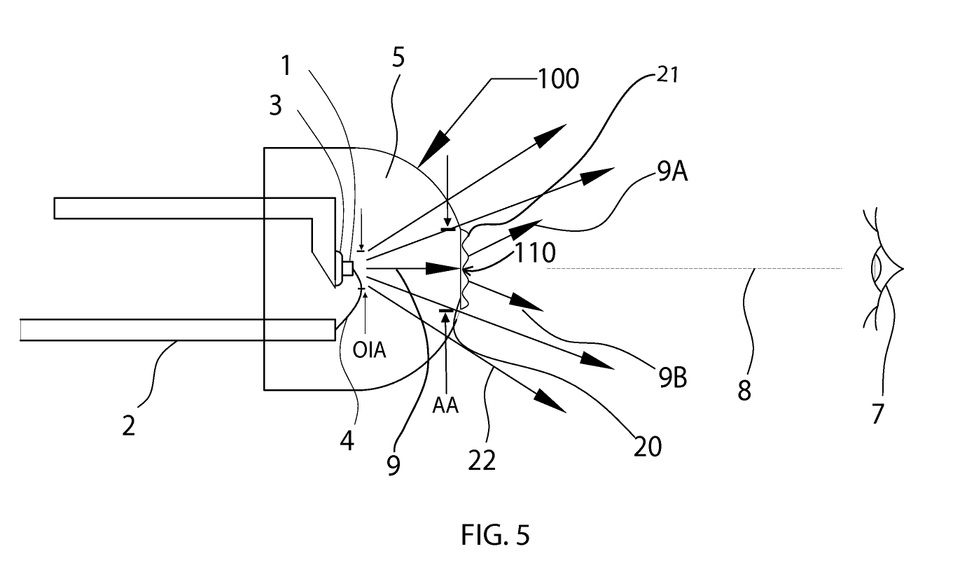

The additional new structure is described as follows with reference to FIGS. 4 and 5. A planar surface of the compound abraded light scattering area (CALSA) 110 is formed on the LED 100. This CALSA 110 is formed by processes that include producing a grinded layer 20 in conjunction with an adjacent etched layer 21. This abraded area AA of this CALSA 110 is defined by a dimension such that the size of the grinded layer 20 and etched layer 21 is just larger than the optical imaging area (OIA) of the emission area of the light-emitting wafer 1. Therefore it follows that AA>OIA.

Procedures for providing this dual layer abraded area AA, includes grinding a portion of the light emissions area. The tip of the epoxy resin encapsulation layer 5 of the LED 100 is grinded. This step is to create a planar, flat platform for next step. The next step of the process of making the dual layer abraded area AA is etching and thus forming an etched layer 21. By using etching such as laser etching or chemical etching or any suitable known methods of etching, an uneven, scattering surface is created on the flat light emitting platform to act as a scattering lens. Besides etching, any other methods such as molding are also feasible to apply. The major purpose of this step is to create an uneven surface such that this abraded area AA of this CALSA 110 functions as a scattering lens. The abraded area AA of the uneven surface is just large enough to cover the imaging emission area of the light-emitting wafer 1.

FIG. 5 is a schematic diagram illustrating how the light beams emit from the Intensity Scattering LED 100 to the human eye 7 (and human body) by way of this dual layered abraded area AA. The light beams 22 that are not on the normal line 8 remain unchanged and the intensity still remains unchanged. However, the light beam 9A and 9B that were originally on the normal line 8 are now scattered by the uneven surface scattering lens formed by the abraded area AA. Therefore, it can greatly increase the safety level as the light beam on the normal line 8 is scattered so the intensity to the human eye or human body is decreased while simultaneously the total intensity and the brightness of the LED remains unchanged.

This invention can apply to all kind of LED's, and the LED may be a conventional pin package having two or more supporting legs and/or SMD (Surface Mount Device) package having no supporting legs but having two or more connecting pads. Moreover, beyond LED's, the inventive concepts of the instant invention may be employed on other optical devices such as an optoelectronic device selected from the group consisting of light emitting diodes, photodiodes, phototransistors, light sensors, reflective sensors, photo interrupters, and receiver modules

It is to be appreciated that one or more of the elements depicted in the drawings/figures can also be implemented in a more separated or integrated manner, or even removed or rendered as inoperable in certain cases, as is useful in accordance with a particular application. It is also within the spirit and scope of the present invention to implement a program or code that can be stored in a machine-readable medium to permit a computer to perform or assist with any of the methods and procedures for manufacturing the apparatus described herein.

Thus, while the present invention has been described herein with reference to particular embodiments thereof, a latitude of modification, various changes and substitutions are intended in the foregoing disclosures, and it will be appreciated that in some instances some features of embodiments of the invention will be employed without a corresponding use of other features without departing from the scope and spirit of the invention as set forth. Therefore, many modifications may be made to adapt a particular situation or material to the essential scope and spirit of the present invention. It is intended that the invention not be limited to the particular terms used and/or to the particular embodiment disclosed as the best mode contemplated for carrying out this invention, but that the invention will include any and all embodiments and equivalents falling within the scope of the instant disclosure.

For example, the LED wafer may be bonded by a single conductive wire, or multiple wires. A product may have one or several wafer, depending on the features needed. The set of lead frames may have two or more supporting legs, or none at all (surface mounted device). Moreover, a pigment, diffusing agent or fluorescent phosphor powder may be added into the LED or the epoxy layer. The pigment makes the LED or the epoxy layer colorful; the diffusing agent allows the entirety of the LED or the epoxy layer to emit light; and the fluorescent phosphor powder is capable of changing the wavelength and therefore changing the color of the emitted light. The light-emitting intensity and the color of the emitted light is determined by the wafer, however the wafer does not make any color, it is the fluorescent phosphor powder that is added that can change and modify the color.

The foregoing description of illustrated embodiments of the present invention, including what is described in the Abstract, is not intended to be exhaustive or to limit the invention to the precise forms disclosed herein. While specific embodiments of, and examples for, the invention are described herein for illustrative purposes only, various equivalent modifications are possible within the spirit and scope of the present invention, as those skilled in the relevant art will recognize and appreciate. As indicated, these modifications may be made to the present invention in light of the foregoing description of illustrated embodiments of the present invention and are to be included within the spirit and scope of the present invention.

What is claimed is:

1. A light scattering light emitting diode apparatus, comprising:
at least one light emitting wafer;
said wafer operatively coupled to a power source via a set of conductive lead wires,
a set of conductive lead frames, and wherein said optoelectronic device and said IC wafer are operatively and electrically coupled to said conductive lead frames,
a transparent epoxy housing fully encapsulating said light emitting wafer and at least partially encapsulating said conductive lead frames;
and said insulating, transparent epoxy housing having scattering lens formed by a dual abraded area comprised of a first grinded layer and a second etched layer.

2. The light scattering light emitting diode apparatus of claim 1,
wherein said grinded layer and said etched layer are adjacent each other; and
wherein said grinded area is sized and configured to be disposed adjacent to the light emitting wafer and is an inner layer of said epoxy housing;
and the etched layer is sized and configured to be disposed adjacent to said grinded layer and forms the outer layer of said epoxy housing;

3. The light scattering light emitting diode apparatus of claim 2,
wherein the light emitting surface of the epoxy housing forming the scattering lens is planar.

4. The light scattering light emitting diode apparatus of claim 3,
wherein said light emitting diode device may further comprise optoelectronic devices selected from the group consisting of light emitting diodes, photodiodes, phototransistors, light sensors, reflective sensors, photo interrupters, and receiver modules.
